(19) United States
(12) Patent Application Publication
(10) Pub. No.: US 2010/0242275 A1
(43) Pub. Date: Sep. 30, 2010

(54) METHOD OF MANUFACTURING AN INSPECTION APPARATUS FOR INSPECTING AN ELECTRONIC DEVICE

(75) Inventors: Woo-Chang Choi, Busan (KR); Jung-Min Ha, Seoul (KR); Yong-Ji Lee, Gyeonggi-do (KR); Ji-Hee Hwang, Gyeonggi-do (KR); Sung-Jae Oh, Seoul (KR)

Correspondence Address: DALY, CROWLEY, MOFFORD & DURKEE, LLP, SUITE 301A, 354A TURNPIKE STREET, CANTON, MA, 02021-2714, US

(73) Assignee: Phicom Corproation

(21) Appl. No.: 12/739,044

(22) PCT Filed: Oct. 22, 2008
(86) PCT No.: PCT/KR08/06239

§ 371 Date: Apr. 21, 2010

(30) Foreign Application Priority Data
Oct. 22, 2007 (KR) 10-2007-0105882

(51) Int. Cl. H05K 3/00

(52) U.S. Cl. 29/850

(57) ABSTRACT

In a method of manufacturing an inspection apparatus for inspecting an electronic device, a sacrificial substrate is formed into a substrate pattern including a through-hole. A principal substrate including an internal wiring penetrating from a first surface to a second surface thereof is combined with the substrate pattern in such a configuration that the through-hole is positioned over the internal wiring, thereby forming a combined structure. A filling structure is formed in the through-hole of the substrate pattern, and the filling structure is electrically connected to the internal wiring of the principal substrate. The substrate pattern is removed from the combined structure, and thus the filling structure is formed into a probe structure on the principal substrate. The probe structure may be connected to the principal substrate without any adhesives such as a solder, to thereby prevent electrical resistance increase and excessive thermal stress.

### TECHNICAL FIELD

Example embodiments of the present invention relate to a method of manufacturing an apparatus for inspecting electric devices, and more particularly, to a method of manufacturing an inspection apparatus having a probe structure in which at least one micro tip is installed and makes direct contact with an inspection object in an electric inspection process.

### BACKGROUND ART

Semiconductor devices are generally manufactured through a series of unit processes such as a fab process, an electrical die sorting (EDS) process and a packaging process. Various electric circuits and devices are fabricated on a semiconductor substrate such as a silicon wafer in the fab process, and electrical characteristics of the electric circuits are inspected and defective chips are detected in the EDS process. Then, when the defective chips are detected in a predetermined allowable range, devices are individually separated from the wafer and each device is sealed in an epoxy resin and packaged into an individual semiconductor device in the packaging process.

The EDS process is generally performed using an inspection apparatus in which a probe card is installed. An electrical signal is applied by an electric inspection apparatus to an electrode pad of a chip on a silicon wafer through a micro tip, widely known as a probe tip, which makes contact with the electrode pad of the chip. Then, the electric inspection apparatus receives a response signal from the electrode pad of the chip through the probe tip and detects whether or not the chip is operating normally. Therefore, the EDS process is usually performed by the electric inspection apparatus including the probe tip making contact with the electrode pad of the chip. A conventional electric inspection apparatus includes a first substrate to which the probe structure is mounted, a second substrate to which electric signals are transferred from the first substrate and a connection member electrically connecting the first and second substrates.

The probe structure is usually combined to the first substrate by a bonding agent such as a solder. Particularly, the probe structure is electrically connected to the first substrate by a bonding process.

However, the conventional bonding of the probe structure and the first substrate causes problems of high electrical resistance and thermal stress. The bonding agent, for example, the solder, impedes the flow of electrons between the probe structure and the first substrate to thereby increase the electrical resistance of the probe structure. In addition, the bonding process, particularly, as for the soldering process, is performed at a high temperature of about 300 C, and thus both the probe structure and the first substrate experience high thermal stress.

Accordingly, the conventional electric inspection apparatus has low electrical reliability due to the high electrical resistance of the probe structure and low manufacturing efficiency due to the high thermal stress on the probe structure and the first substrate.

### DISCLOSURE OF INVENTION

### Technical Problem

Example embodiments of the present invention provide a method of manufacturing an electric inspection apparatus in which the probe structure and the substrate are bonded together with each other without a bonding agent.

### Technical Solution

According to an aspect of the present invention, there is provided a method of manufacturing an inspection apparatus for inspecting an electronic device. A sacrificial substrate is provided and then the sacrificial substrate is formed into a substrate pattern including a through-hole. A principal substrate is formed to have first and second surfaces and an internal wiring that penetrates the principal substrate between the first and second surfaces. The substrate pattern is combined with the principal substrate in such a configuration that the through-hole is positioned over the internal wiring, thereby forming a combined structure. A filling structure is formed in the through-hole of the substrate pattern, and the filling structure is electrically connected to the internal wiring of the principal substrate. The substrate pattern is removed from the combined structure, so that the filling structure is formed into a probe structure on the principal substrate.

According to another aspect of the present invention, there is provided a method of manufacturing an inspection apparatus for inspecting an electronic device. A sacrificial substrate including silicon is provided and the sacrificial substrate is formed into a substrate pattern including a through-hole having an overturned L shape, so that the substrate pattern includes a shoulder of which the thickness is smaller than that of the sacrificial substrate. A seed layer is formed on the shoulder of the substrate. A principal substrate is formed to have first and second surfaces and an internal wiring for electrically connecting conductive structures on the first and second surfaces of the principal substrate. The principal substrate includes ceramic materials. A surface wiring is formed on the first surface of the principal substrate and the surface wiring is electrically connected to the internal wiring. A photoresist film is formed on the first surface of the principal substrate. The substrate pattern is brought into contact with the first surface of the principal substrate in such a configuration that the through-hole is positioned over the surface wiring, and then the substrate pattern is combined with the principal substrate by baking the photoresist film, thereby forming a combined structure. A photoresist pattern is formed between the substrate pattern and the principal substrate by removing the photoresist film exposed through the through-hole from the principal substrate, so that the surface wiring is exposed through the through-hole. A filling structure is formed in the through-hole, so that the filling structure is electrically connected to the surface wiring. The substrate pattern, the photoresist pattern and the seed layer are removed from the combined structure, so that the filling structure is formed into a probe structure on the principal substrate.

In an example embodiment, the seed layer includes titanium (Ti), copper (Cu) or combinations thereof, and the filling structure includes nickel (Ni), cobalt (Co) or combinations thereof. The photoresist film is baked at a temperature of about 80 C to about 150 C. A micro tip is further formed on the probe structure, and thus the micro tip makes direct contact with the electronic device in an inspection process.

### ADVANTAGEOUS EFFECTS

According to the example embodiments of the present invention, a probe structure is electrically connected to a principal substrate by a photoresist film, so that the probe structure and the principal substrate are directly combined with each other without any bonding agents such as a solder.

Accordingly, electrical resistance increase of the probe structure due to the bonding agent may be sufficiently prevented, which may improve the electrical reliability of the inspection apparatus. In addition, excessive thermal stress due to a bonding process between the probe structure and the principal substrate under high temperature may be prevented, which may improve the manufacturing efficiency of the inspection apparatus.

### BRIEF DESCRIPTION OF THE DRAWINGS

The above and other features and advantages of the invention will become readily apparent by reference to the following detailed description when considered in conjunction with the accompanying drawings wherein:

FIGS. 1 to 4 are cross-sectional views illustrating manufacturing steps for forming a sacrificial pattern on a substrate for an electric inspection apparatus in accordance with an example embodiment of the present invention;

FIGS. 5 to 7 are cross-sectional views illustrating manufacturing steps for forming a principal substrate for an electric inspection apparatus in accordance with an example embodiment of the present invention;

FIGS. 8 to 13 are cross-sectional views illustrating processing steps for manufacturing an electric inspection apparatus in accordance with an example embodiment of the present invention; and

FIG. 14 is a view schematically illustrating an electric inspection apparatus in accordance with an example embodiment of the present invention.

### BEST MODE FOR CARRYING OUT THE INVENTION

The invention is described more fully hereinafter with reference to the accompanying drawings, in which embodiments of the invention are shown. This invention may, however, be embodied in many different forms and should not be construed as limited to the embodiments set forth herein. Rather, these embodiments are provided so that this disclosure will be thorough and complete, and will fully convey the scope of the invention to those skilled in the art. In the drawings, the size and relative sizes of layers and regions may be exaggerated for clarity.

It will be understood that when an element or layer is referred to as being “on,” “connected to” or “coupled to” another element or layer, it can be directly on, connected or coupled to the other element or layer or intervening elements or layers may be present. In contrast, when an element is referred to as being “directly on,” “directly connected to” or “directly coupled to” another element or layer, there are no intervening elements or layers present. Like numbers refer to like elements throughout. As used herein, the term “and/or” includes any and all combinations of one or more of the associated listed items.

It will be understood that, although the terms first, second, third etc. may be used herein to describe various elements, components, regions, layers and/or sections, these elements, components, regions, layers and/or sections should not be limited by these terms. These terms are only used to distinguish one element, component, region, layer or section from another region, layer or section. Thus, a first element, component, region, layer or section discussed below could be termed a second element, component, region, layer or section without departing from the teachings of the present invention.

Spatially relative terms, such as “beneath,” “below,” “lower,” “above,” “upper” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the exemplary term “below” can encompass both an orientation of above and below. The device may be otherwise oriented (rotated 90 degrees or at other orientations) and the spatially relative descriptors used herein interpreted accordingly.

The terminology used herein is for the purpose of describing particular embodiments only and is not intended to be limiting of the invention. As used herein, the singular forms “a,” “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

Embodiments of the invention are described herein with reference to cross-section illustrations that are schematic illustrations of idealized embodiments (and intermediate structures) of the invention. As such, variations from the shapes of the illustrations as a result, for example, of manufacturing techniques and/or tolerances, are to be expected. Thus, embodiments of the invention should not be construed as limited to the particular shapes of regions illustrated herein but are to include deviations in shapes that result, for example, from manufacturing. For example, an implanted region illustrated as a rectangle will, typically, have rounded or curved features and/or a gradient of implant concentration at its edges rather than a binary change from implanted to non-implanted region. Likewise, a buried region formed by implantation may result in some implantation in the region between the buried region and the surface through which the implantation takes place. Thus, the regions illustrated in the figures are schematic in nature and their shapes are not intended to illustrate the actual shape of a region of a device and are not intended to limit the scope of the invention.

Unless otherwise defined, all terms (including technical and scientific terms) used herein have the same meaning as commonly understood by one of ordinary skill in the art to which this invention belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

Hereinafter, the present invention will be described in detail with reference to the accompanying drawings.

### Method of Manufacturing an Electric Inspection Apparatus

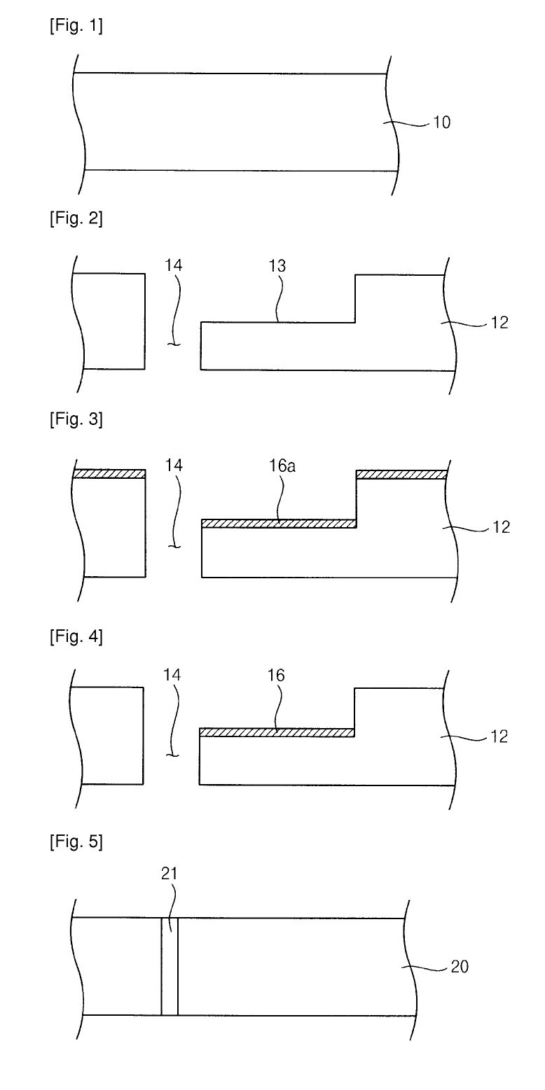

FIGS. 1 to 4 are cross-sectional views illustrating manufacturing steps for forming a sacrificial pattern on a substrate for an electric inspection apparatus in accordance with an example embodiment of the present invention.

Referring to FIG. 1, a sacrificial substrate 10 is provided and a sacrificial pattern is formed on the sacrificial substrate 10 for a probe structure. For example, the sacrificial substrate may include a silicon substrate that has advantages of good process ability and excellent adhesive properties to photoresist films.

Referring to FIG. 2, the sacrificial substrate 10 is formed into a substrate pattern 12 including a through-hole 14 having an overturned L shape and a shoulder 13 having a smaller thickness than that of the sacrificial substrate 10. In an example embodiment, patterning of the sacrificial substrate 10 may be performed by a photolithography process and an etching process.

Although the above preferred embodiment discloses the overturn L-shaped through-hole 14 as the substrate pattern, a cylindrical through-hole or any other shape and configurations known to one of the ordinary skill in the art may also be utilized in place of or in conjunction with the overturn L-shaped through-hole 14 as the substrate pattern. In the present example embodiment, the substrate pattern is formed into the overturn L-shaped through-hole to have a cantilever-type probe structure.

Referring to FIGS. 3 and 4, a seed layer 16 is formed on the shoulder 13 of the substrate pattern 12. The seed layer 16 may comprise a conductive material. Examples of the conductive material may include titanium (Ti) and copper (Cu). These may be used alone or in combinations thereof. For example, the seed layer 16 may include a multilayer structure in which a titanium layer and a copper layer are sequentially stacked on each other. A filling structure, which is described in detail hereinafter, may be formed to have a uniform top surface by the seed layer 16.

In an example embodiment, a preliminary seed layer 16a is formed on the substrate pattern 12 by a thin-film process such as an evaporation process, a deposition process and a plating process. That is, the preliminary seed layer 16a is formed on an upper surface and on the shoulder 13 of the substrate pattern 12. Then, the preliminary seed layer 16a is removed from the upper surface of the substrate pattern 12 by a planarization process such as a chemical mechanical polishing (CMP) process, and thus remains only on the shoulder 13 of the substrate pattern 12.

Accordingly, the seed layer 16 is formed only on the shoulder 13 of the substrate pattern 12 by a sequential process of the formation of the preliminary seed layer 16a and the partial removal of the preliminary seed layer 16a.

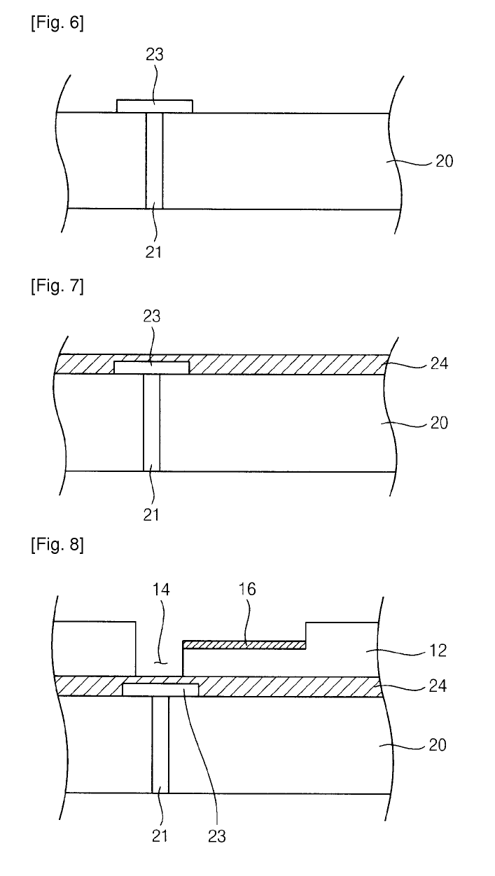

FIGS. 5 to 7 are cross-sectional views illustrating manufacturing steps for forming a principal substrate for an electric inspection apparatus in accordance with an example embodiment of the present invention.

Referring to FIG. 5, a principal substrate 20 including an internal wiring 21 may be provided as a first substrate for an electric inspection apparatus. For example, the principal substrate 20 may include a ceramic substrate. The internal wiring 21 may be exposed from upper and lower surfaces of the principal substrate 20, so that a first structure on the upper surface of the principal substrate 20 may be electrically connected to a second structure on the lower surface of the substrate 20 by the internal wiring 21. In the present example embodiment, the first structure may include a probe structure described in detail hereinafter and the second structure may include a second substrate that is also described in detail hereinafter.

While the present example embodiment discloses the internal wiring may penetrate the principal substrate and be exposed from the upper and lower surfaces, any other modifications known to one of ordinary skill in the art may also be utilized only if the internal wiring is positioned in an inside of the principal substrate.

The principal substrate 20 may function as a micro probe head (MPH) and a space transformer when the electric inspection apparatus includes a probe card.

Referring to FIG. 6, a surface wiring 23 is formed on the upper surface of the principal substrate 20 by a sequential process of deposition and patterning and is electrically connected to the internal wiring 21. The surface wiring 23 may be electrically connected to the probe structure on the upper surface of the principal substrate 20, and thus the surface wiring 23 may be omitted in a case where the probe structure makes direct contact with the internal wiring 21 on the upper surface of the principal substrate 20.

A protective layer (not shown) may be further formed on the lower surface of the principal substrate 20, and thus the protective layer may be positioned opposite to the surface wiring 23. For example, the protective layer may comprise titanium (Ti), copper (Cu) or include a photoresist film. The protective layer may prevent the filling structure from being formed on the lower surface of the principal substrate 20.

Referring to FIG. 7, a bonding member 24 may be formed on the upper surface of the principal substrate 20 on which the surface wiring 23 is formed. For example, the bonding member 24 may include photoresist compositions that have sufficient adhesiveness due to a baking process to the bonding member 24.

For the above reason, a photoresist film may be formed on the upper surface of the principal substrate 20 on which the surface wiring 23 is formed as the bonding member 24.

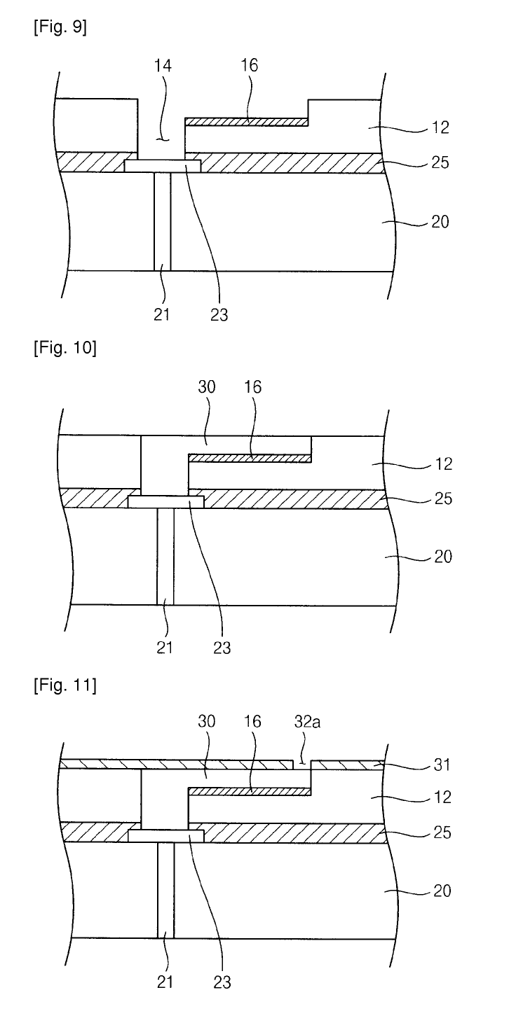

FIGS. 8 to 13 are cross-sectional views illustrating processing steps for manufacturing an electric inspection apparatus in accordance with an example embodiment of the present invention.

Referring to FIG. 8, the substrate pattern 12 may be brought into contact with the upper surface of the principal substrate 20 in such a configuration that the through-hole 14 of the substrate pattern 12 is positioned over the surface wiring 23 of the principal substrate 20. In a case where no surface wiring 23 is formed on the principal substrate 20, the substrate pattern 12 is brought into contact with the upper surface of the principal substrate 20 in such a configuration that the through-hole 14 of the substrate pattern 12 is positioned over the internal wiring 21 of the principal substrate 20.

Then, the substrate pattern 12 and the principal substrate 20 are combined to each other by a bonding member 24 such as a photoresist film. That is, the combination of the substrate pattern 12 and the principal substrate 20 may be performed by the excellent adhesiveness of the photoresist film, and thus a baking process may be performed right after the substrate pattern 12 is brought onto the principal substrate 20.

Therefore, the principal substrate 20 and the substrate pattern 12 may be sufficiently secured to each other by the baking process to the bonding member 24 such as the photoresist film.

When the baking process is performed at a temperature below about 80 C, the photoresist film may not have sufficient adhesive properties between the principal substrate 20 and the substrate pattern 12, and when the baking process is performed at a temperature above about 150 C, the principal substrate 20 may experience excessive thermal stress. For that reason, the baking process may be performed at a temperature of about 80 C to about 150 C, and more particularly, about 90 C to about 130 C. In the present example embodiment, the baking process is performed at a temperature of about 100 C to about 120 C, and more particularly, about 110 C.

In an example embodiment, the photoresist film 24 may be formed to a sufficient thickness in view of the aspect ratio of the through-hole 14 of the substrate pattern 12. A sufficient thickness may allow the through-hole 14 to have a sufficient aspect ratio, and thus the probe structure, which is described in detail hereinafter, may have a sufficient height because the probe structure is formed in the through-hole 14 of the substrate pattern 12.

Referring to FIG. 9, the photoresist film 24 exposed through the through-hole 14 may be removed from the principal substrate 20, to thereby expose the surface wiring 24 through the through-hole 14. For example, the photoresist film 24 may be removed from the principal substrate 20 by an etching process using the substrate pattern as an etching mask.

Accordingly, the photoresist film 24 may be formed into a first photoresist pattern 25 between the principal substrate 20 and the substrate pattern 12 and the surface wiring 23 of the principal substrate 20 may be partially exposed through the through-hole 14 of the substrate pattern 12.

Referring to FIG. 10, a filling structure 30 is formed in the through-hole 14 of the substrate pattern 12. The filling structure 30 is to be formed into the probe structure through the following steps. In an example embodiment, the filling structure 30 may include nickel (Ni) and cobalt (Co). These may be used alone or in combinations thereof. In the present example embodiment, the filling structure 30 may comprise combinations of nickel (Ni) and cobalt (Co).

A filling layer (not shown) may be formed on the substrate pattern 12 to a sufficient thickness to fill up the through-hole 14 by an evaporation process, a sputtering process, a deposition process or a plating process, and the filling layer is planarized by a planarization process such as a CMP process until a top surface of the substrate pattern 12 is exposed. As a result, the filling layer remains only in the through-hole 14 of the substrate pattern 12, to thereby form the filling structure 30 in the through-hole 14.

As described above, the seed layer 16 on the shoulder 13 of the substrate pattern 12 may allow the filling structure 30 to have a uniform top surface.

Therefore, the filling structure 30 may be formed in the through-hole 14 of the substrate pattern 12 and be electrically connected to the surface wiring 23 of the principal substrate 20.

Referring to FIGS. 11 and 12, a tip layer 32 is formed at an end portion of the filling structure 30. The tip layer 32 is formed into a micro tip of the probe structure.

In an example embodiment, a second photoresist pattern 31 is formed on the substrate pattern 12 including the filling structure 30 in such a configuration that the entire surface of the substrate pattern 12 except for the end portion of the filling structure 30 is covered with the second photoresist pattern 31 and the end portion of the filling structure 30 is exposed through an opening 32a of the second photoresist pattern 31. Then, the tip layer 32 is filled into the opening 32a of the second photoresist pattern 31. In the present example embodiment, the tip layer 32 may include the same material as the filling structure 30 such as nickel (Ni), cobalt (Co) or combinations thereof.

While the above example embodiment discloses one tip layer on the filling structure 30, one or more tip layers may be formed on the filling layer 30 in accordance with manufacturing conditions and apparatus requirements, as would be known to one of the ordinary skill in the art.

Referring to FIG. 13, the substrate pattern 12, the seed layer 16 and the first and second photoresist patterns 25 and 31 are removed from the principal substrate 20, to thereby form a probe structure 35 on the principal substrate 20. That is, the probe structure 35 may be electrically connected to the surface wiring 23 of the principal substrate 20 and a micro tip 37 is positioned at the end portion.

According to example embodiments, the substrate pattern 12 and the principal substrate 20 are bonded to each other by the bonding member 24, such as the photoresist film, and the probe structure 35 is formed on the principal substrate 20. Therefore, the probe structure 35 may be electrically connected to the principal substrate 20 without any adhesives such as a solder.

### Electric Inspection Apparatus

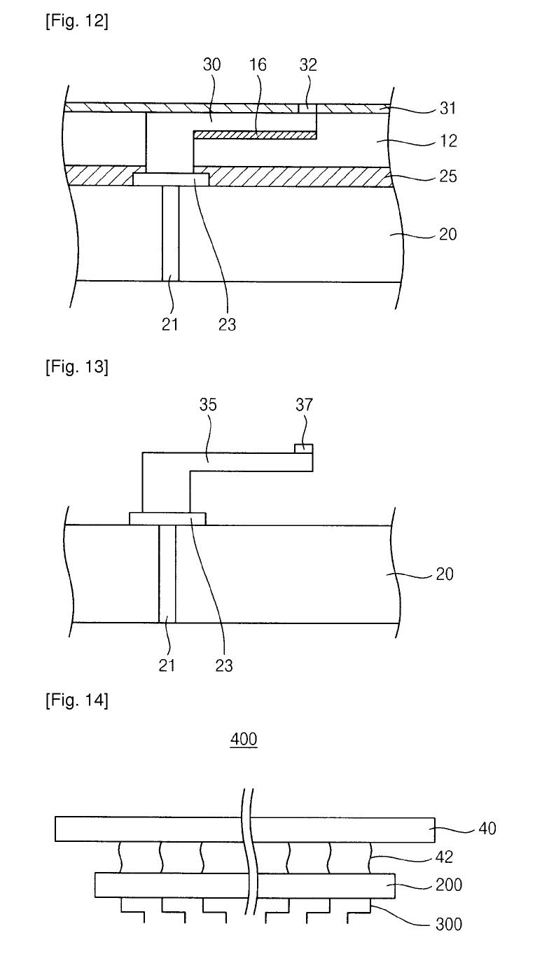

FIG. 14 is a view schematically illustrating an electric inspection apparatus in accordance with an example embodiment of the present invention.

Referring to FIG. 14, an inspection apparatus 400 in accordance with an example embodiment of the present invention may include a first substrate 200 having a probe tip 300, a second substrate 40 electrically connected to the first substrate 200 and a connector 42 electrically connecting the first and second substrates 200 and 40 with each other. In the present example embodiment, the principal substrate 20 having the probe structure 35 and the micro tip 37, which is described with reference to FIGS. 5 to 7, may be used as the first substrate 200 having the probe tip 300.

For example, the second substrate 40 may include a printed circuit board (PCB) and the connector 42 may include a pogo pin and an interposer.

The inspection apparatus 400 including the first substrate 200 and the probe structure 35 on which the micro tip 37 is mounted may be utilized for inspecting defects of electric devices such as a conventional probe card.

### INDUSTRIAL APPLICABILITY

According to the example embodiments of the present invention, a substrate pattern and a principal substrate are bonded to each other by a bonding member such as a photoresist film and a probe structure is formed on the principal substrate. Therefore, the probe structure may be electrically connected to the principal substrate without any adhesives such as a solder, to thereby prevent electrical resistance increase and excessive thermal stress.

Although the exemplary embodiments of the present invention have been described, it is understood that the present invention should not be limited to these exemplary embodiments but various changes and modifications can be made by one skilled in the art within the spirit and scope of the present invention as hereinafter claimed.

1. A method of manufacturing an inspection apparatus for inspecting an electronic device, comprising:
providing a sacrificial substrate;
forming the sacrificial substrate into a substrate pattern including a through-hole;
forming a principal substrate having first and second surfaces and an internal wiring that penetrates the principal substrate between the first and second surfaces;
combining the substrate pattern with the principal substrate in such a configuration that the through-hole is positioned over the internal wiring, thereby forming a combined structure;
forming a filling structure in the through-hole of the substrate pattern, the filling structure being electrically connected to the internal wiring of the principal substrate; and
removing the substrate pattern from the combined structure, to thereby forming the filling structure into a probe structure on the principal substrate.

2. The method of claim 1, wherein the sacrificial substrate includes a silicon substrate and the principal substrate includes a ceramic substrate.

3. The method of claim 1, wherein the through-hole is formed into one of a cylindrical shape and an overturned L shape.

4. The method of claim 1, wherein the substrate pattern and the principal substrate are combined by a bonding member interposed between the substrate pattern and the principal substrate.

5. The method of claim 4, wherein the bonding member includes photoresist compositions, so that the combined structure of the substrate pattern and the principal substrate is formed by a baking process performed on the photoresist compositions at a temperature of about 80 C to about 150 C.

6. The method of claim 1, wherein the filling structure comprises nickel (Ni), cobalt (Co) or combinations thereof.

7. The method of claim 1, further comprising forming a surface wiring on the first surface of the principal substrate, the surface wiring being electrically connected to the internal wiring.

8. The method of claim 1, further comprising forming a micro tip on the probe structure, the micro tip making direct contact with the electronic device in an inspection process.

9. A method of manufacturing an inspection apparatus for inspecting an electronic device, comprising:
providing a sacrificial substrate including silicon;
forming the sacrificial substrate into a substrate pattern including a through-hole having an overturned L shape, so that the substrate pattern includes a shoulder of which the thickness is smaller than that of the sacrificial substrate;
forming a seed layer on the shoulder of the substrate;
forming a principal substrate having first and second surfaces and an internal wiring for electrically connecting conductive structures on the first and second surfaces of the principal substrate, the principal substrate including ceramic materials;
forming a surface wiring on the first surface of the principal substrate, the surface wiring being electrically connected to the internal wiring;
forming a photoresist film on the first surface of the principal substrate;
contacting the substrate pattern with the first surface of the principal substrate in such a configuration that the through-hole is positioned over the surface wiring;
combining the substrate pattern with the principal substrate by baking the photoresist film, thereby forming a combined structure;
forming a photoresist pattern interposed between the substrate pattern and the principal substrate by removing the photoresist film exposed through the through-hole from the principal substrate, so that the surface wiring is exposed through the through-hole;
forming a filling structure in the through-hole, so that the filling structure is electrically connected to the surface wiring; and
removing the substrate pattern, the photoresist pattern and the seed layer from the combined structure, so that the filling structure is formed into a probe structure on the principal substrate.

10. The method of claim 9, wherein the seed layer includes titanium (Ti), copper (Cu) and combinations thereof, and the filling structure includes nickel (Ni), cobalt (Co) and combinations thereof.

11. The method of claim 9, wherein baking the photoresist film is performed at a temperature of about 80 C to about 150 C.

12. The method of claim 9, further comprising forming a micro tip on the probe structure, the micro tip making direct contact with the electronic device in an inspection process.
